(19) United States
(12) Patent Application Publication
(10) Pub. No.: US 2008/0060838 A1
(43) Pub. Date: Mar. 13, 2008

(54) Flip chip substrate structure and the method for manufacturing the same

(75) Inventors: Bo-Wei Chen, Hsinchu (TW); Hsien-Shou Wang, Hsinchu (TW); Shih-Ping Hsu, Hsinchu (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/519,896

(22) Filed: Sep. 13, 2006

(51) Int. Cl. H05K 1/11; H01R 12/04

(52) U.S. Cl. 174/262

(57) ABSTRACT

A flip chip substrate structure and a method to fabricate thereof are disclosed. The structure comprises a build up structure, a first solder mask and a second solder mask. Plural first and second electrical contact pads are formed on the first and second surface of the build up structure, respectively. A first solder mask having plural openings is formed on the first surface of the build up structure, and the openings expose the first electrical contact pads, wherein the aperture of the openings of the first solder mask are equal to the outer diameter of the first electrical contact pads. A second solder mask having plural openings is formed on the second surface of the build up structure, and the openings expose the second electrical contact pads, wherein the aperture of the openings of the second solder mask are smaller than the outer diameter of the second electrical contact pads.

### BACKGROUND OF THE INVENTION

1. Field of the Invention

The present invention relates to a flip chip structure, the method to manufacture the same and, more particularly, to a flip chip substrate structure that applies to non-through hole structures and improves circuit integration, and a method to manufacture flip chip substrates with a streamlined process.

2. Description of Related Art

With the development of the IT industry, the research in the industry is gradually turning to multifunctional and high performance electronic products. To meet the demands for high integration and miniaturization of semiconductor packaging, the circuit boards providing circuit connections among active and passive components are evolving from double layer boards to multi-layer boards in order to expand available layout areas on circuit boards within limited spaces by interlayer connection techniques, so as to accommodate the requirement of high circuit layout density of integrated circuits.

The semiconductor packaging structures known in the art are fabricated by adhering a semiconductor chip on the top of the substrate, proceeding with wire bonding or flip chip packaging, and then mounting solder balls on the back of the substrate for electrical connection. Though a high pin quantity can be obtained, operations at higher frequencies or speeds are restricted due to unduly long lead routes and consequent limited performance. Besides, multiple connection interfaces are required in conventional packaging, leading to increased process complexity.

In the method to manufacture flip chip substrates, the fabrication of a carry board begins with a core substrate, which is then subjected to drilling, electroplating, hole-plugging, and circuit formation to accomplish the internal structure. A multi-layer carry board is then obtained through build up processes, as the method to fabricate build up multi-layered boards shown in FIGS. 1A to 1E. Referring to FIG. 1A, a core substrate 11 is first prepared, which is composed of a core layer 111 having a predetermined thickness and circuit layers 112 formed on the surface thereof. Meanwhile, a plurality of plated through hole 113 are formed in the core layer 111 to electrically connect the circuit layers 112. Referring to FIG. 1B, the core substrate 11 is subjected to a build up process so as to overlay a dielectric layer 12 on the surface of the core substrate 11, wherein the dielectric layer 12 has a plurality of openings that are corresponding to the circuit layer 13. Referring to FIG. 1C, a seed layer 14 is formed by electroless plating or sputtering on the exposed portions of the dielectric layer 12, wherein a patterned resist layer 15 is formed on the seed layer 14, and a plurality of openings 150 are formed in the resist layer 15 to expose the portions of seed layer that are set to be a patterned circuit layer. Referring to FIG. 1D, a patterned circuit layer 16 and plural conductive vias 13a are formed in the openings of the resist layer by electroplating, the resist layer 15 and the portions of seed layer 14 covered therebeneath are removed by etching, such that a first build up structure 10a is formed. Referring to FIG. 1E, a second build up structure is formed on the outer surface of the first build up structure in the same manner, repeating the same build up procedures to form a multi-layered carry board.

However, the aforementioned process begins with a core substrate, which is subjected to drilling, electroplating, hole-plugging, and circuit formation to form the internal structure. Then a multi-layered carry board is formed through a build up process. The method has problems such as low integration, multiple layers, long leads and high resistance, rendering it less applicable to high-frequency semiconductor package substrates. Due to its multiple layers, the process procedures are complex and the process cost is higher.

### SUMMARY OF THE INVENTION

In view of the foregoing disadvantages, the object of the present invention is to provide a flip chip substrate structure that can reduce the substrate thickness and achieve the purpose of miniaturization.

To achieve this, one object of the present invention is to provide a flip chip structure, comprising: at least a build up structure having a metal layer formed on the first surface to electrically connection with which, and a circuit layer of the build up structure formed on the second surface; a first solder mask, which is formed on the first surface of the build up structure, and plural openings are formed on the first solder mask in order to expose the metal layer of the first surface as first electrical contact pads, wherein the aperture of the openings of the first solder mask are equal to the outer diameter of the first electrical contact pads; and a second solder mask, which is formed on the second surface of the build up structure, and plural openings are formed on the second solder mask in order to expose the circuit layer of the second surface as second electrical contact pads, wherein the aperture of the openings of the second solder mask are smaller than the outer diameter of the second electrical contact pads.

According to the flip chip substrate structure of the present invention, further comprising plural solder bumps, which are formed on the first and second electrical contact pads.

According to the flip chip substrate structure of the present invention, metal posts are first formed on the first and second electrical contact pads before formation of the above-mentioned build up structure. The material of the metal posts is preferably at least one selected from the group consisting of copper, nickel, chromium, titanium, copper/chromium alloys, and tin/lead alloy. More preferably, the material is copper.

According to the flip chip substrate structure of the present invention, wherein a etching-stop layer and metal posts are first formed on the first and second electrical contact pads before formation of solder bumps.

According to the flip chip substrate structure of the present invention, further comprising a holding element, which is mounted upon the contour of the second solder mask to prevent the substrate from warping.

According to the flip chip substrate structure of the present invention, there is no particular limitation to the material of the first and the second solder masks, and they can same or different photo-sensitive materials, preferably photo-sensitive polymers.

According to the flip chip substrate structure of the present invention, the build up structure has at least one seed layer having an electroplating metal layer formed thereon. The seed layer is at least one selected from the group consisting of copper, tin, nickel, chromium, titanium, copper-chromium alloy, and tin-lead alloy. The seed layer employs conductive polymers as the seed layer, and the conductive polymers are at least one selected from the group consisting of polyacetylene, polyaniline, and organic sulfur polymers. Besides, the electroplating metal layer is a copper layer.

According to the flip chip substrate structure of the present invention, the material of the first and second electrical contact pads is preferably copper. In addition, there is no particular limitation to the material of the solder bumps, but it is preferably at least one selected from the group consisting of copper, tin, lead, silver, nickel, gold, platinum, and the alloys thereof.

According to the flip chip substrate structure of the present invention, the etching-stop layer is at least one selected from the group consisting of: iron, nickel, chromium, titanium, aluminum, silver, tin, lead, and the alloys thereof.

Another object of the present invention is to provide a method to fabricate a flip chip substrate, which can increase circuit integration and streamline process procedures.

The flip chip substrate structure of the present invention can be fabricated by the following (but not limited to) procedures:

Providing a carry board, forming a first solder mask on the carry board, wherein plural first openings are formed in the first solder mask. A conductive metal layer, an etching-stop layer, and a metal layer are formed orderly upward in the first openings of the first solder mask, and then at least one build up structure is formed on the surfaces of the metal layer and the first solder mask. Subsequently, a second solder mask is formed on the at least one build up structure, and plural openings are formed in the second solder mask to expose portions of the build up structure as second electrical contact pads. The carry board, the conductive metal layer and the etching-stop layer are removed to expose the metal layer in the first openings of the first solder mask, which serves as first electrical contact pads of the other side. Finally, plural solder bumps are formed on the first and second electrical contact pads.

According to the method to fabricate the flip chip substrate of the present invention, the etching-stop layer can proceed with subsequent process without removal if its material is metal inert to oxidation, wherein the metal is gold.

According to the method to fabricate the flip chip substrate of the present invention, metal posts can be firstly formed on the first and second electrical contact pads before formation of the solder bumps, wherein the material of the metal posts is preferably at least one selected from the group consisting of copper, nickel, chromium, titanium, copper/chromium alloys, and tin/lead alloy. More preferably, the material is copper.

According to the method to fabricate the flip chip substrate of the present invention, further comprising a holding element, which is mounted upon the contour of the second solder mask to prevent the substrate from warping.

According to the method to fabricate the flip chip substrate of the present invention, there is no particular limitation to the material of the carry board, but preferably it is copper.

According to the method to fabricate the flip chip substrate of the present invention, there is no particular limitation to the method to form the first openings of the first solder mask, but preferably it is by exposure and development. The conductive metal layer, the etching-stop layer, and the metal layer are preferably formed by electroplating or electroless plating.

According to the method to fabricate the flip chip substrate of the present invention, the materials of the seed layer and the metal layer can be identical or different, but preferably are at least one selected from the group consisting of copper, nickel, chromium, titanium, copper/chromium alloy, and tin/lead alloy.

According to the method to fabricate the flip chip substrate of the present invention, the procedures to form the at least one build up structure comprise:

Forming a dielectric layer on the surfaces of the metal layer and the first solder mask, and forming plural third openings in the dielectric layer, wherein at least one of the third openings corresponds to the metal layer; forming a seed layer on the surfaces of the dielectric layer and the third openings; forming a patterned resist layer on the seed layer, which functions in formation of plural resist layer openings, wherein at least one of the resist layer openings corresponds to the metal layer; electroplating an electroplating metal layer in the plural resist layer openings; removing the plural resist layers and the seed layer covered therebeneath, such that a desirable multi-layered build up structure is obtained through the above-mentioned steps.

According to the method to fabricate the flip chip substrate of the present invention, the dielectric layer in the aforementioned procedures is selected from the group consisting of: ABF(Ajinomoto Build up Film), BCB(Benzocyclo-buthene), LCP(Liquid Crystal Polymer), PI(Poly-imide), PPE(Poly(phenylene ether)), PTFE(Poly(tetra-fluoroethylene)), FR4, FR5, BT(Bismaleimide Triazine), Aramide, other photo-sensitive and non-photo-sensitive organic resins, and mixtures of epoxy resins and glass fibers. The seed layer serves as the current conductive routes in the following electroplating process. When it is at least one selected from the group consisting of copper, tin, nickel, chromium, titanium, copper/chromium alloy, and tin/lead alloy, it is formed by sputtering, vapor deposition, electroless plating, or CVD. When conductive polymers are employed to form the seed layer, it is formed by spin coating, ink-jet printing, screen printing, or imprinting, wherein the conductive polymers are at least one selected from the group consisting of polyacetylene, polyaniline, and organic sulfur polymers. There is no particular limitation to the electroplating metal layer, preferably it is copper, nickel, chromium, palladium, titanium, tin/lead or the alloys thereof; more preferably, it is copper.

According to the method to fabricate the flip chip substrate of the present invention, there is no particular limitation to formation of the second openings in the second solder mask, preferably they are formed by exposure and development.

Other objects, advantages, and novel features of the invention will become more apparent from the following detailed description when taken in conjunction with the accompanying drawings.

### BRIEF DESCRIPTION OF THE DRAWINGS

FIG. 1A to 1E is the cross-section of a prior art flip chip substrate having a core layer;

FIG. 2A to 2Q′ is the cross-section of a flip chip substrate of one preferred embodiment of the present invention; and

FIG. 3A to 3P′ is the cross-section of a flip chip substrate of another preferred embodiment of the present invention.

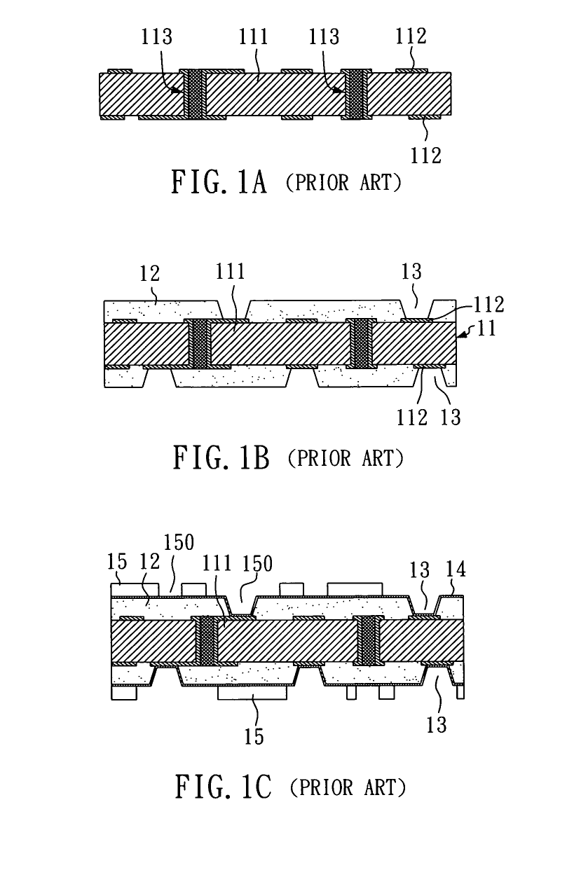

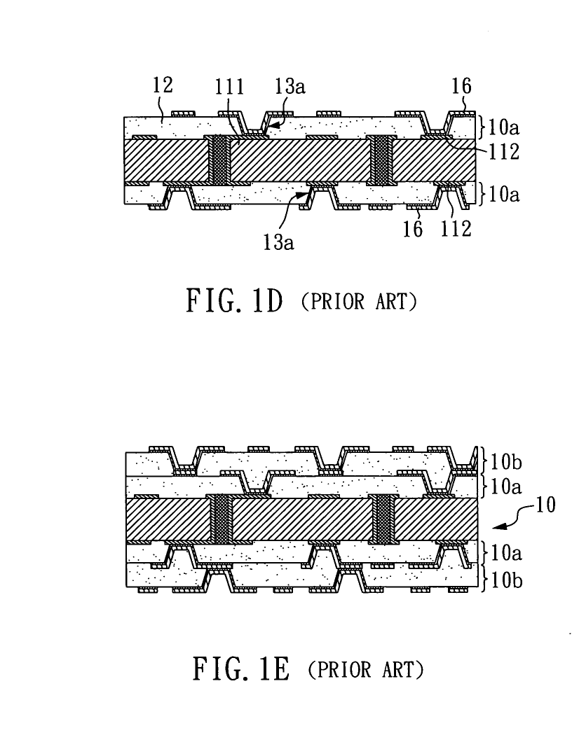

### DETAILED DESCRIPTION OF THE PREFERRED EMBODIMENT

### Example 1

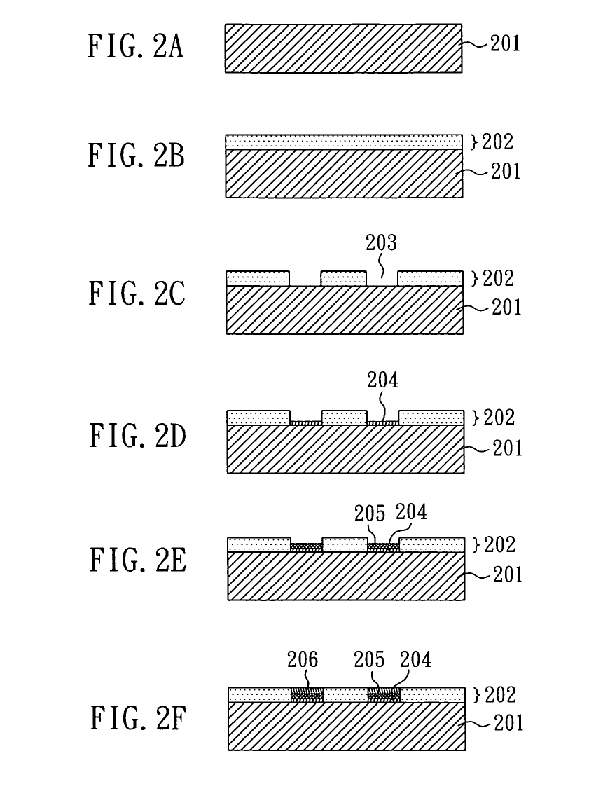

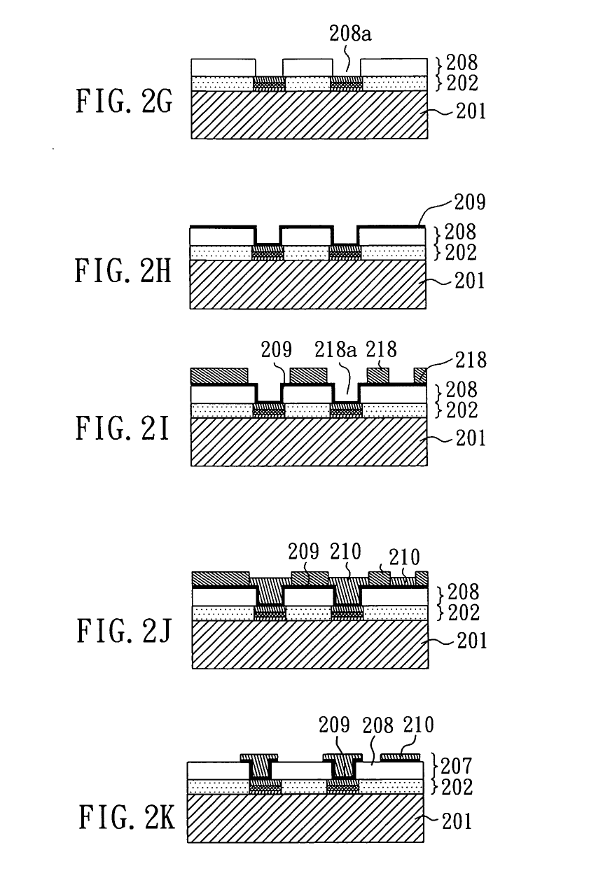

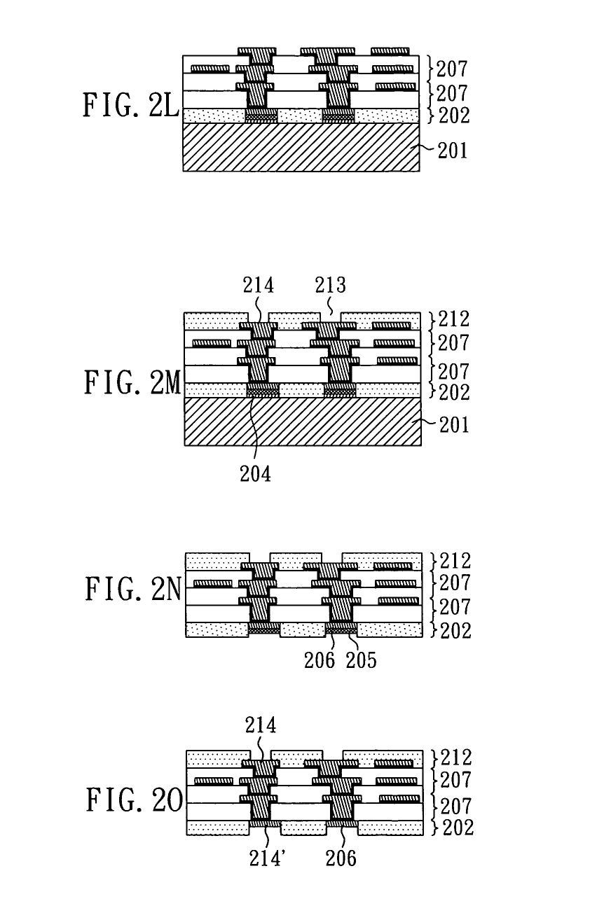

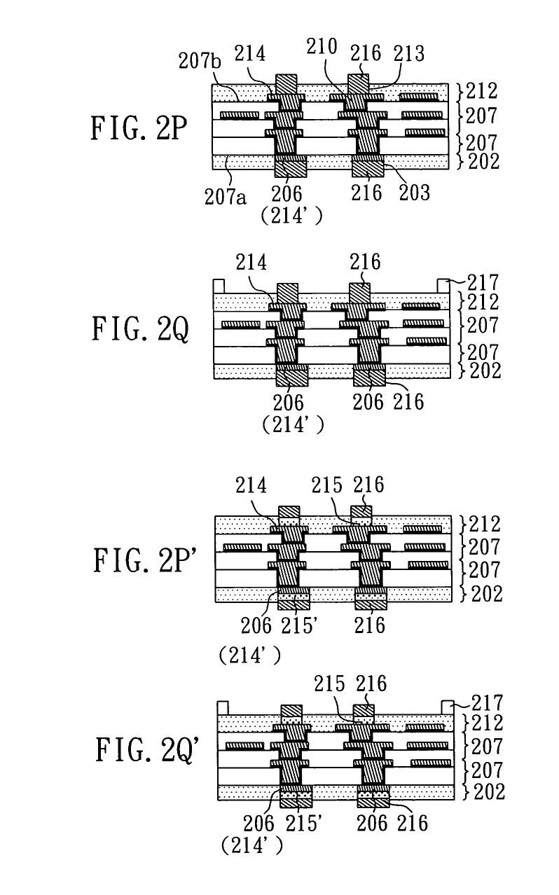

FIGS. 2A-2Q illustrate the cross-section of one embodiment of the flip chip substrate structure of the present invention. First, as shown in FIG. 2A, a carry board is provided, which is a metal plate, preferably a copper plate. Then, as shown in FIG. 2B, a first solder mask 202 is coated on the carry board 201, and plural first openings 203 are formed by exposure and development, as shown in FIG. 2C. A conductive metal layer 204, an etching-stop layer 205 and a metal layer 206 are formed orderly upward by electroplating or electroless plating, as shown in FIGS. 2D-2F, wherein the materials of the conductive metal layer 204 and the metal layer 206 are copper, and the material of the etching-stop layer 205 is at least one selected from the group consisting of iron, nickel, chromium, titanium, aluminum, silver, tin, lead or the alloys thereof.

Referring to FIG. 2G, a dielectric layer 208 is formed on the surfaces of the metal layer 206 and the first solder mask 202, wherein the dielectric layer 208 is selected from the group consisting of: ABF(Ajinomoto Build up Film), BCB(Benzocyclo-buthene), LCP(Liquid Crystal Polymer), PI(Poly-imide), PPE(Poly(phenylene ether)), PTFE(Poly(tetra-fluoroethylene)), FR4, FR5, BT(Bismaleimide Triazine), and Aramide, other photo-sensitive and non-photo-sensitive organic resins, or mixtures of epoxy and glass fibers. Plural third openings 208a are formed by means of laser drilling, exposure or development in the dielectric layer 208, wherein at least one of the third openings 208a corresponds to the positions of the metal layer 206. Note that de-smear processes must be performed to remove the smears generated in the dielectric layer openings when laser drilling is employed. As shown in FIG. 2H, a seed layer 209 is formed on the surface of the dielectric layer 208 and the openings 208a, which serves as a current conducting route during electroplating and comprises at least one selected from the group consisting of copper, tin, nickel, chromium, titanium, copper-chromium alloy, and tin-lead alloy, formed by at least one approach selected from the group consisting of sputtering, vapor deposition, electroless plating, and CVD. Besides, the seed layer 209 can comprise conductive polymers, which are at least one selected from the group consisting of polyacetylene, polyaniline, and organic sulfur polymers, and the seed layer 209 is formed by means of spin coating, ink-jet printing, screen printing, or imprinting.

Subsequently, as shown in FIG. 21, a patterned resist layer 218a is formed on the seed layer 209, which is used to form plural resist layer openings 218a by exposure and development, wherein at least one resist layer opening corresponds to the positions of the metal layer 206. Referring to FIG. 2J, the plural resist openings 218a are electroplated with an electroplating metal layer 210, the electroplating metal layer 210 is most preferably copper, then the resist layer 218 and the seed layer 209 covered therebeneath are removed by etching, and a build up structure 207 is obtained, as shown in FIG. 2K.

Referring to FIG. 2L, an additional build up structure 207 can be formed on the initial build up structure 207 in the same manner as the above-mentioned. Referring to FIG. 2M, a second solder mask 212 is overlaid upon the at least one build up structure, and plural second openings 213 are formed in the second solder mask 212 by exposure and development to expose the portions of the build up structure that serve as second electrical contact pads 214.

Then, as shown in FIG. 2N, the carry board 201 and the conductive metal layer 204 are removed by etching and, as shown in FIG. 20, the etching-stop layer is etched to expose the metal layer 206 that will serve as first electrical contact pads 214′ on the other side.

Further referring to FIG. 2P, solder bumps 216 are formed directly on the electrical contact pads (i.e. first electrical contact pads 214′ and second electrical contact pads 214), and the method to form the solder bumps can be electroplating or printing. Alternatively, as shown in FIG. 2P′, if needed, metal posts 215 can be formed first by electroplating in the second openings 213 of the second solder mask 212, the material of the metal posts 215 is copper; metal posts 215′ are formed by electroplating onto the metal layer 206, wherein the material of the metal posts 215′ is copper; then, solder bumps 216 are formed respectively on the metal posts 215 and 215′. The method to form the solder bumps 216 can be electroplating or printing, and the material of the solder bumps is at least one selected from the group consisting of copper, tin, lead, silver, nickel, gold, platinum, and the alloys thereof.

Finally, as shown in FIGS. 2Q and 2Q′, a holding element 217 is mounted upon the contour of the second solder mask 212, which is used to prevent the substrate from warping.

The present invention provides a flip chip substrate structure, as shown in FIG. 2P, comprising: at least a build up structure 207, a first solder mask 202 and a second solder mask 212. A metal layer 206 is formed on the first surface 207a to electrically connection with the build up structure 207, and a circuit layer of the build up structure 207 (i.e. formed by portions of the electroplating metal layer 210) formed on the second surface 207b of the build up structure 207. A first solder mask 202 is formed on the first surface 207a of the build up structure 207, and plural openings (i.e. first opening 203) are formed on the first solder mask 202 in order to expose the metal layer 206 of the first surface 207a as first electrical contact pads 214′, wherein the aperture of the openings of the first solder mask 202 are equal to the outer diameter of the first electrical contact pads 214′. A second solder mask 212 is formed on the second surface 207b of the build up structure 207, and plural openings (i.e. second openings 213) are formed on the second solder mask 212 in order to expose the circuit layer of the second surface 207b as second electrical contact pads 214, wherein the aperture of the openings of the second solder mask 212 are smaller than the outer diameter of the second electrical contact pads 214.

### Example 2

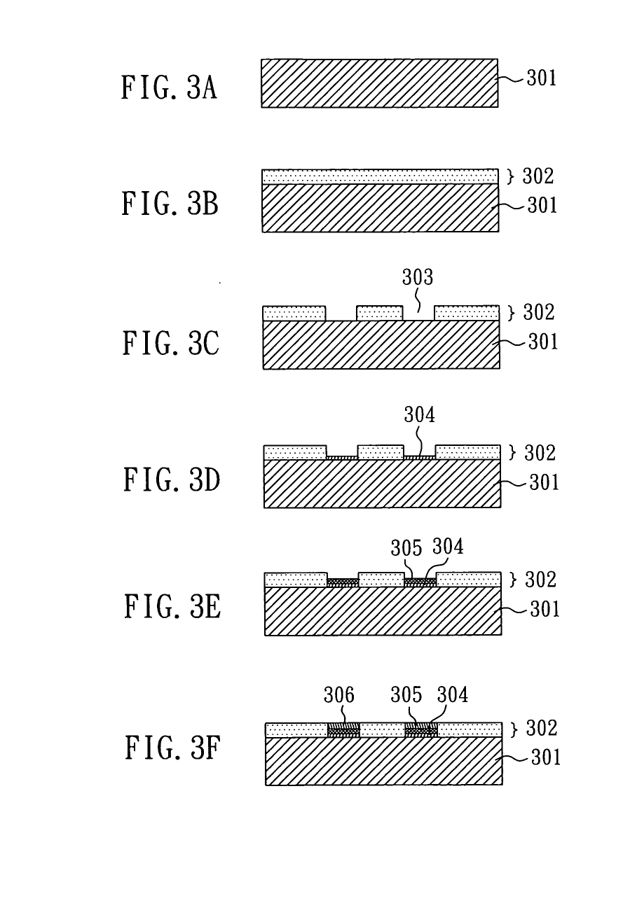

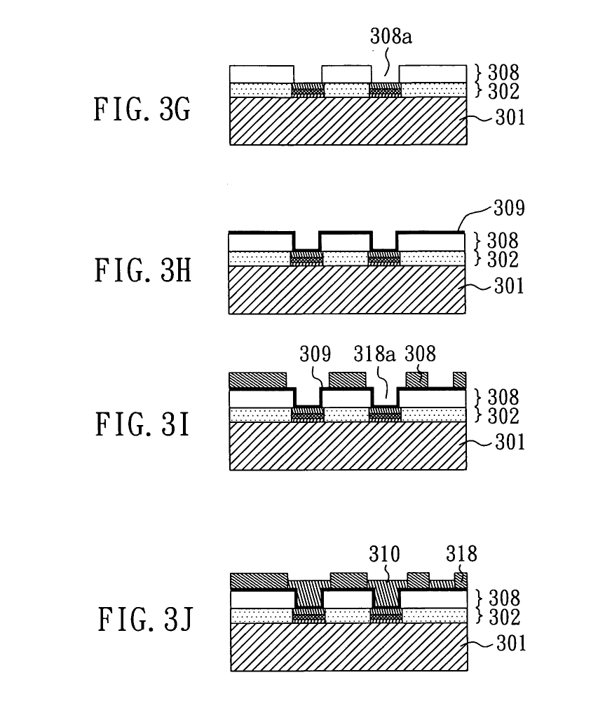

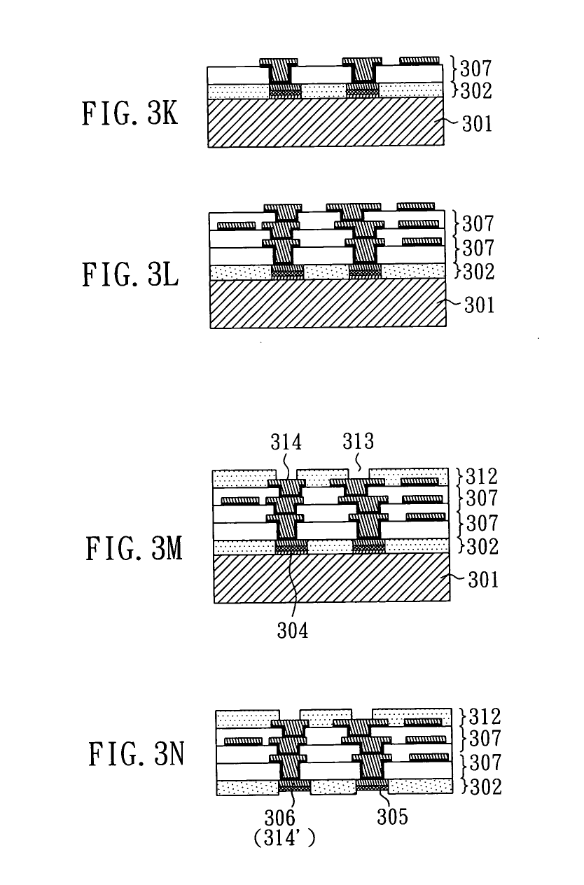

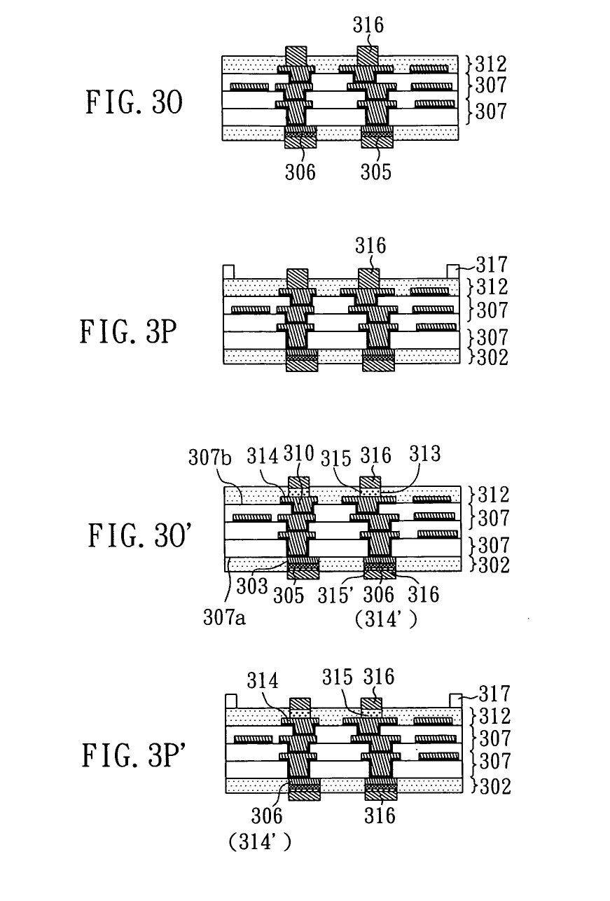

Please refer to FIGS. 3A to 3P to see the cross-section of another embodiment of the flip chip substrate structure of the present invention.

First, as shown in FIG. 3A, a carry board 301 is provided, which is a metal plate, preferably copper. Then, as shown in FIG. 3B, a first solder mask 302 is overlaid on the carry board 301, and plural first openings 303 are formed by exposure and development in the first solder mask 302, as shown in FIG. 3C.

A conductive metal layer 304, an etching-stop layer 305 and a metal layer 306 are formed orderly upward by electroplating or electroless plating in the first openings 303 of the first solder mask 302, which are depicted in FIGS. 3D to 3F, wherein the material of the conductive metal layer 304 and the metal layer 306 is copper, and the material of the etching-stop layer is gold because of its resistance to oxidation.

Subsequently, as shown in FIG. 3Q a dielectric layer 308 is formed on the surface of the metal layer 306 and the first solder layer 302, wherein the dielectric layer is selected from the group consisting of ABF(Ajinomoto Build up Film), BCB(Benzocyclo-buthene), LCP(Liquid Crystal Polymer), PI(Poly-imide), PPE(Poly(phenylene ether)), PTFE(Poly(tetra-fluoroethylene)), FR4, FR5, BT(Bismaleimide Triazine), and Aramide, other photo-sensitive and non-photo-sensitive organic resins, or mixtures of epoxy and glass fibers. Plural third openings 308a are formed by means of laser drilling, exposure or development in the dielectric layer 308, wherein at least one of the third openings 308a corresponds to the positions of the metal layer 304. Note that de-smear processes must be performed to remove the smears generated in the dielectric layer openings when laser drilling is employed. As shown in FIG. 3H, a seed layer 309 is formed on the surface of the dielectric layer 308 and the openings 308a, which serves as a current conducting route during electroplating and comprises at least one metal selected from the group consisting of copper, tin, nickel, chromium, titanium, copper-chromium alloy, and tin-lead alloy, formed by at least one approach selected from the group consisting of sputtering, vapor deposition, electroless plating, and CVD. Besides, the seed layer 309 can comprise conductive polymers, which are at least one selected from the group consisting of polyacetylene, polyaniline, and organic sulfur polymers, and the seed layer 309 is formed by means of spin coating, ink-jet printing, screen printing, or imprinting.

Subsequently, as shown in FIG. 31, a patterned resist layer 318 is formed on the seed layer 309, which is used to form plural resist layer openings 318a by exposure and development, wherein at least one resist layer opening 318a corresponds to the positions of the metal layer 306. Referring to FIG. 3J, the plural resist openings 318a are electroplated with an electroplating metal layer 310, the electroplating metal layer 310 is most preferably copper, then the resist layer 318 and the seed layer 309 covered therebeneath are removed by etching, and a build up structure 307 is obtained, as shown in FIG. 3K.

Referring to FIG. 3L, an additional build up structure 307 can be formed on the initial build up structure 307 in the same manner as the above-mentioned. Referring to FIG. 3M, a second solder mask 312 is overlaid upon the at least one build up structure 307. Plural second openings 313 are formed in the second solder mask 312 by exposure and development to expose the portions of the build up structure circuits that serve as second electrical contact pads 314.

Then, as shown in FIG. 3N, the carry board 301 and the conductive metal layer 304 are removed by etching to expose the etching-stop layer 305 that will serve as first electrical contact pads 314′ on the other side.

Further referring to FIG. 3O, solder bumps 316 are formed directly on the electrical contact pads (i.e. first electrical contact pads 314′ and second electrical contact pads 314), and the method to form the solder bumps can be electroplating or printing. Alternatively, as shown in FIG. 3O′, if needed, metal posts 315 can be formed first by electroplating in the second openings 313 of the second solder mask 312, the material of the metal posts 315 is copper; metal posts 315′ are then formed by electroplating onto the etching-stop layer 305, wherein the material of the metal posts 315′ is copper; then, solder bumps 316 are formed respectively on the metal posts 315 and 315′. The method to form the solder bumps 316 can be electroplating or printing, and the material of the solder bumps 316 is at least one selected from the group consisting of copper, tin, lead, silver, nickel, gold, platinum, and the alloys thereof.

Finally, as shown in FIGS. 3P and 3P′, a holding element 317 is mounted upon the contour of the second solder mask 312, which is used to prevent the substrate from warping.

The present invention provides a flip chip substrate structure, as shown in FIG. 3O′, comprising: at least a build up structure 307, a first solder mask 302 and a second solder mask 312. A metal layer 306 is formed on the first surface 307a to electrically connection with the build up structure 307, and a circuit layer of the build up structure 307 (i.e. formed by portions of the electroplating metal layer 310) formed on the second surface 307b of the build up structure 307. A first solder mask 302 is formed on the first surface 307a of the build up structure 307, and plural openings (i.e. first opening 303) are formed on the first solder mask 302 in order to expose the metal layer 306 of the first surface 307a as first electrical contact pads 314′, wherein the aperture of the openings of the first solder mask 302 are equal to the outer diameter of the first electrical contact pads 314′. A second solder mask 312 is formed on the second surface 307b of the build up structure 307, and plural openings (i.e. second openings 313) are formed on the second solder mask 312 in order to expose the circuit layer of the second surface 307b as second electrical contact pads 314, wherein the aperture of the openings of the second solder mask 312 are smaller than the outer diameter of the second electrical contact pads 314. However, an etching-stop layer 305 and metal posts 315 can be formed first on the first electrical contact pads 314′ before formation of plural solder bumps 316, and metal posts 315 can be formed first on the second electrical contact pads 314 before formation of plural solder bumps 316.

In sum, the present invention solves the problems of low integration, too many layers, long leads and high resistance in carry boards having core substrates known in the art. The non-through holes structure increases circuit integration, streamlines the process, reduces thickness and achieves the purpose of miniaturization.

Although the present invention has been explained in relation to its preferred embodiment, it is to be understood that many other possible modifications and variations can be made without departing from the scope of the invention as hereinafter claimed.

What is claimed is:

1. A flip chip substrate structure, comprising:
at least a build up structure having a metal layer formed on the first surface to electrically connection with which, and a circuit layer of the build up structure formed on the second surface;
a first solder mask, which is formed on the first surface of the build up structure, and plural openings are formed on the first solder mask in order to expose the metal layer of the first surface as first electrical contact pads, wherein the aperture of the openings of the first solder mask are equal to the outer diameter of the first electrical contact pads; and
a second solder mask, which is formed on the second surface of the build up structure, and plural openings are formed on the second solder mask in order to expose the circuit layer of the second surface as second electrical contact pads, wherein the aperture of the openings of the second solder mask are smaller than the outer diameter of the second electrical contact pads.

2. The flip chip substrate structure of claim 1, further comprising plural solder bumps, which are formed on the first and second electrical contact pads.

3. The flip chip substrate structure of claim 1, wherein metal posts are first formed on the first and second electrical contact pads before formation of the build up structure.

4. The flip chip substrate structure of claim 1, wherein an etching-stop layer and metal posts are first formed on the first and second electrical contact pads before formation of the solder bumps.

5. The flip chip substrate structure of claim 1, further comprising a holding element, which is mounted upon the contour of the second solder mask to prevent the substrate from warping.

6. The flip chip substrate structure of claim 1, wherein the first and second electrical contact pads are copper.

7. The flip chip substrate structure of claim 4, wherein the material of the etching-stop layer is gold.

8. The flip chip substrate structure of claim 4, wherein the material of the metal post is copper.

9. A method to fabricate a flip chip substrate, comprising the following steps:
providing a carry board;
forming a first solder mask on the carry board, wherein plural first openings are formed in the first solder mask;
forming a conductive metal layer, an etching-stop layer, and a metal layer orderly upward in the first openings of the first solder mask;
forming at least one build up structure on the surfaces of the metal layer and the first solder mask;
forming a second solder mask on the build up structure, and plural openings are formed in the second solder mask to expose portions of the build up structure as second electrical contact pads; and
removing the carry board, the conductive metal layer and the etching-stop layer to expose the metal layer in the first openings of the first solder mask, which serves as first electrical contact pads of the other side.

10. The method to fabricate the flip chip substrate of claim 9, wherein plural solder bumps are formed on the first and second electrical contact pads.

11. The method to fabricate the flip chip substrate of claim 9, wherein the material of the etching-stop layer is at least one selected from the group consisting of iron, nickel, chromium, titanium, aluminum, silver, tin, lead, and the alloys thereof.

12. The method to fabricate the flip chip substrate of claim 9, wherein the etching-stop layer can proceed with subsequent process without removal if its material is metal inert to oxidation.

13. The method to fabricate the flip chip substrate of claim 12, wherein the metal inert to oxidation is gold.

14. The method to fabricate the flip chip substrate of claim 9, wherein metal posts are firstly formed on the first and second electrical contact pads before formation of the solder bumps.

15. The method to fabricate the flip chip substrate of claim 9, further comprising a holding element mounted upon the contour of the second solder mask to prevent the substrate from warping.

16. The method to fabricate the flip chip substrate of claim 9, wherein the procedures to form the at least one build up structure comprises:
forming a dielectric layer on the surfaces of the metal layer and the first solder mask, and forming plural third openings in the dielectric layer, wherein at least one of the third openings corresponds to the metal layer;
forming a seed layer on the surfaces of the dielectric layer and the third openings;
forming a patterned resist layer on the seed layer, which functions in formation of plural resist layer openings, wherein at least one of the resist layer openings corresponds to the metal layer;
electroplating an electroplating metal layer in the plural resist layer openings; and
removing the plural resist layers and the seed layer covered therebeneath.

17. The method to fabricate the flip chip substrate of claim 9, wherein the carry board, the conductive metal layer and the etching-stop layer are removed by etching.

18. The method to fabricate the flip chip substrate of claim 9, wherein the material of the metal posts is copper.

19. The method to fabricate the flip chip substrate of claim 9, wherein the material of the solder bumps is at least one selected from the group consisting of copper, tin, lead, silver, nickel, gold, platinum, and the alloys thereof.

20. The method to fabricate the flip chip substrate of claim 18, wherein the method to form the metal posts is electroplating.

21. The method to fabricate the flip chip substrate of claim 18, wherein the method to form the solder bumps is electroplating or printing.
